(19) United States
(12) Patent Application Publication
(10) Pub. No.: US 2005/0142803 A1
(43) Pub. Date: Jun. 30, 2005

(54) Method for forming trench isolation in semiconductor device

(75) Inventor: In-Kyu Chun, Suwon-city (KR)

Correspondence Address: THE LAW OFFICES OF ANDREW D. FORTNEY, PH.D., P.C., 7257 N. MAPLE AVENUE, BLDG. D, 3107, FRESNO, CA, 93720, US

(73) Assignee: DongbuAnam Semiconductor Inc.

(21) Appl. No.: 11/026,915

(22) Filed: Dec. 30, 2004

(30) Foreign Application Priority Data
Dec. 31, 2003 (KR) 10-2003-0101794

(51) Int. Cl. H01L 21/76

(52) U.S. Cl. 438/424

(57) ABSTRACT

Disclosed is a method for forming a trench device isolation film in a semiconductor device, which is capable of preventing voids from being generated, regardless of the trench aspect ratio. The method includes forming a trench in a device isolation field of a semiconductor substrate using a mask pattern on the semiconductor substrate, implanting oxygen in a lower portion of the trench, filling the trench with a fill insulating film, and stabilizing the implanted oxygen as an oxide film by annealing and/or compacting the fill insulating film.

### CLAIM OF PRIORITY

This application makes reference to, incorporates the same herein, and claims all benefits accruing under 35 U.S.C. §119 from an application for METHOD FOR FABRICATING THE TRENCH ISOLATION IN SEMICONDUCTOR DEVICE filed in the Korean Industrial Property Office on Dec. 31, 2003 and there duly assigned Serial No. 10-2003-0101794.

### BACKGROUND OF THE INVENTION

(a) Field of the Invention

The present invention relates to a method for fabricating a semiconductor device, and more particularly to a method for forming trench isolation in a semiconductor device.

(b) Description of the Related Art

A device isolation field is necessarily used to electrically isolate devices formed on the same substrate and to prevent effects of parasitic components caused by substrate interconnections. The device isolation field is generally formed using a LOCOS process or a trench formation process.

With the development of semiconductor fabrication techniques, semiconductor devices have been rapidly accelerated in their speed and integration. According to such a trend, the device isolation field has been formed using the trench formation process mainly, rather than the LOCOS process.

FIGS. 1 to 3 are sectional views illustrating a method for forming a trench device isolation film in a conventional semiconductor device, and for explaining problems of the same method.

Referring to FIG. 1, first, a first oxide film 102, a nitride film 104, a second oxide film 106, and a mask pattern 108 are sequentially formed on a semiconductor substrate 100. The mask pattern 108 has an opening for exposing a surface of the second oxide film 106 in a trench device isolation field.

Subsequently, as shown in FIG. 2, a first oxide film pattern 103, a nitride film 105 and a second oxide film pattern 107 for exposing a portion of a surface of the semiconductor substrate 100 are formed by performing an etching process using the mask pattern (108 in FIG. 1) as an etching mask. Next, after the mask pattern 108 is removed, a trench 110 is formed by etching the exposed surface of the semiconductor substrate 100 up to a certain depth.

Subsequently, as shown in FIG. 3, a fill insulating film 112 is formed to fill the trench 110. Thereafter, an annealing process for compacting the fill insulating film 112, a typical planarization process, and an etching process for removing the nitride pattern 105 are performed to complete a trench device isolation film.

In such a conventional method for forming the trench device isolation film, a high density plasma (HDP) oxide film is typically used as the fill insulating film 112. This is because the HDP oxide film has excellent gap fill capability. However, as the trench becomes deeper and narrower and hence an aspect ratio is increasing for attaining higher integration, there arises a problem in that voids are sometimes generated under the fill insulating film 112, as shown in FIG. 3, even when the HDP oxide film with relatively excellent gap fill capability is used.

### SUMMARY OF THE INVENTION

In consideration of the above problem, it is an object of the present invention to provide a method for forming a trench device isolation film in a semiconductor device, which is capable of preventing voids from being generated (or reducing their incidence), regardless of an aspect ratio of a trench.

To achieve the object, according to an aspect of the present invention, there is provided a method for forming a trench device isolation film in a semiconductor device, comprising the steps of:
forming a trench in a device isolation field of a semiconductor substrate using a mask pattern on the semiconductor substrate;
implanting oxygen in a lower portion of the trench;
filling the trench in which the oxygen is implanted with a fill insulating film; and
annealing to compact the fill insulating film and stabilize the implanted oxygen as an oxide film.

Preferably, the mask pattern includes a pad oxide film, a nitride film and a TEOS oxide film, sequentially formed on the semiconductor substrate, configured to expose the device isolation field of the semiconductor substrate.

Preferably, the fill insulating film comprises a high density plasma oxide film.

### BRIEF DESCRIPTION OF THE DRAWINGS

The accompanying drawings, which are incorporated in and constitute a part of the specification, illustrate an embodiment of the invention, and, together with the description, serve to explain the principles of the invention:

FIGS. 1 to 3 are sectional views illustrating a method for forming a trench device isolation film in a conventional semiconductor device, and for explaining problems of the same method; and

FIGS. 4 to 8 are sectional views illustrating a method for forming a trench device isolation film in a semiconductor device according to the present invention.

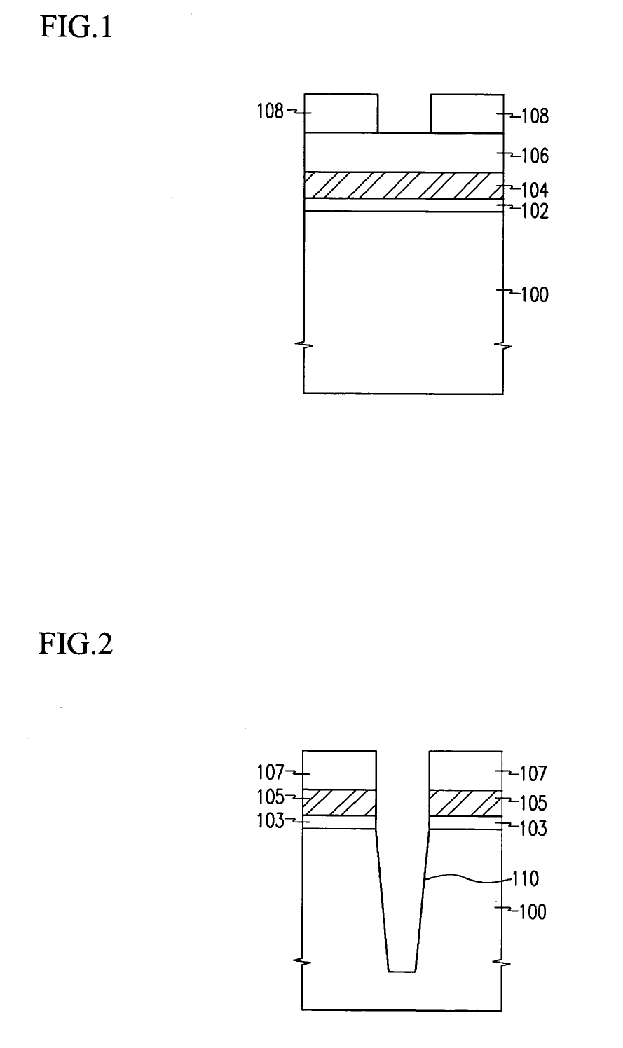

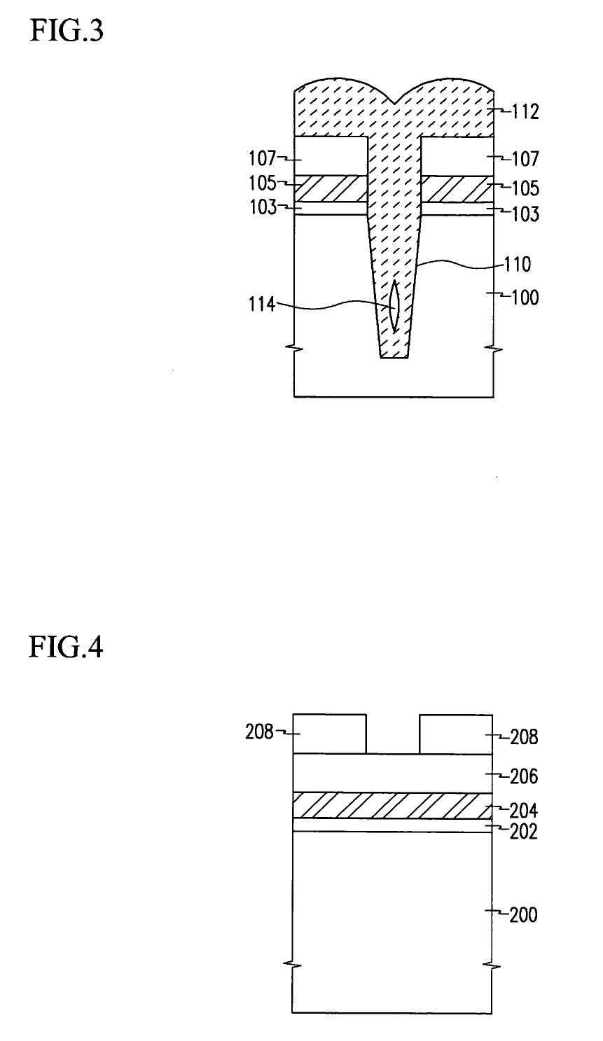

### DETAILED DESCRIPTION OF THE PREFERRED EMBODIMENT

A preferred embodiment of the present invention will now be described in detail with reference to the accompanying drawings. The following embodiments may be modified in various forms, but should not be interpreted to be limited thereto.

FIGS. 4 to 8 are sectional views illustrating a method for forming a trench device isolation film in a semiconductor device according to the present invention.

Referring to FIG. 4, first, a first oxide film 202, a nitride film 204, and a second oxide film 206 are sequentially formed on a semiconductor substrate 200 on which a device isolation film is to be formed. The first oxide film 202 is a pad oxide film for protecting the semiconductor substrate 200, the nitride film 204 is generally used as an etch or polish stop film in a subsequent planarization process, and the second oxide film 206 is used as a hard mask in an etching process for trench formation and may comprise a TEOS oxide film.

In addition, a mask pattern 208, for example, a photoresist pattern, is formed on the second oxide film 206. The mask pattern 208 has an opening for exposing a surface of the second oxide film 206 in a device isolation field.

Subsequently, as shown in FIG. 5, a first oxide film pattern 203, a nitride film pattern 205, and a second oxide film pattern 207 for exposing a surface of the device isolation region of the semiconductor substrate 200 are formed by successively etching second oxide film 206, nitride film 204, and first oxide film 202 using the mask pattern (208 in FIG. 4) as an etching mask.

Next, after removing the mask pattern 208, a trench 210 is formed by etching an exposed surface of the semiconductor substrate 200 up to a certain depth.

The etching operation for forming the trench 210 comprises a dry etching process.

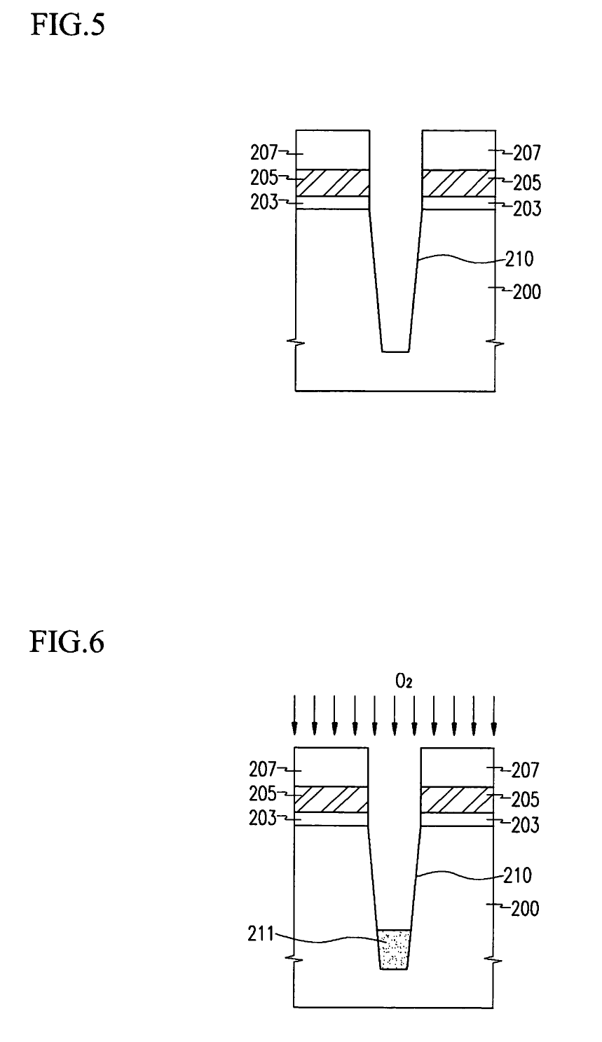

Subsequently, as shown in FIG. 6, an oxygen (O₂) implantation process (indicated by an arrow in the figure) is performed for the entire surface of the structure on which the trench 210 is formed. Thus, oxygen may be blanket-implanted into the entire substrate, including the entire trench. However, due to the geometric configuration of the trench and the directionality of the oxygen implant process, an oxygen implantation region 211 is formed in a lower portion of the trench into which oxygen (O₂) is implanted. While some oxygen may be implanted into the sidewalls of the trench 210, the dose (or, alternatively, the concentration per unit surface area) of implanted oxygen is much higher at the bottom of the trench 210. Thus, oxygen implantation region 211 in the bottom of the trench has an appreciable thickness, whereas any corresponding oxygen implantation regions in the trench sidewalls are very thin, and may be imperceptible. According to this process, the trench 210 becomes shallow (i.e., its depth is smaller after oxygen implantation, relative to before oxygen implantation) and an effective aspect ratio of the trench 210 becomes relatively small due to the oxygen implantation region.

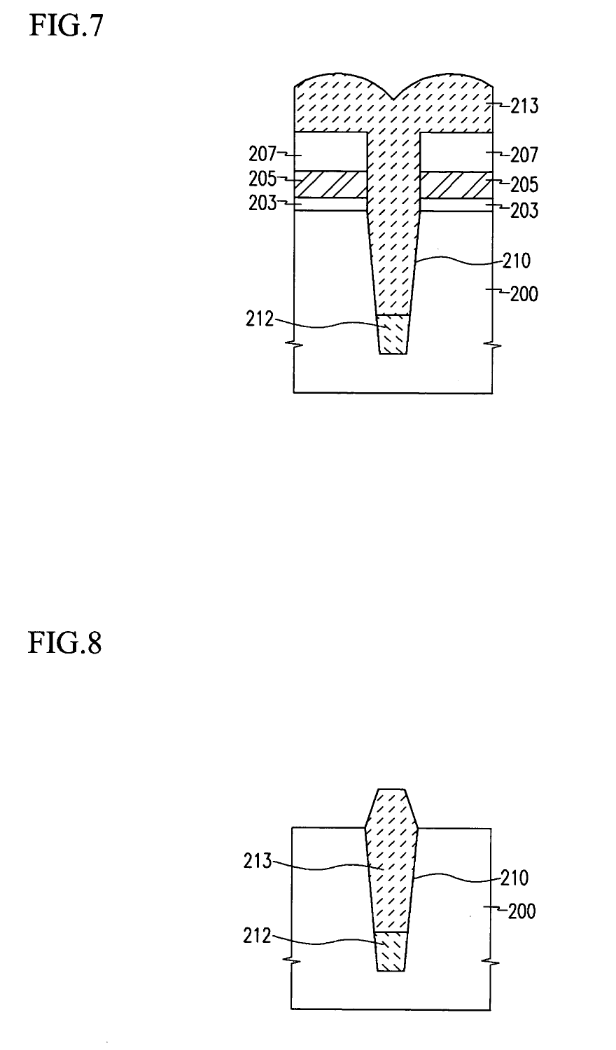

Next, as shown in FIG. 7, the trench 210 is filled with a fill insulating film 213 (preferably, a high density plasma oxide film). When the fill insulating film 213 is formed, since the effective aspect ratio of the trench 210 has been reduced due to the oxygen implant region 211, as described above, generation of voids can be prevented or reduced.

In addition, an annealing process for compacting (or densifying) the fill insulating film 213 is performed. According to this annealing process, the oxygen implantation region (211 in FIG. 6) under the fill insulating film 213 is partially or completely converted to (i.e., stabilized as) an oxide film 212 and acts as a device isolation film together with the fill insulating film 213.

Thereafter, as shown in FIG. 8, a top surface of the fill insulating film 213 and the second oxide film pattern 207 are removed by performing a planarization process (e.g., by CMP) using the nitride film pattern 205 as an etch or polish stop film. Then, when the exposed nitride pattern 205 and the first oxide film pattern 203 are removed, a trench device isolation film having the trench 210 filled with the oxide film 212 and the fill insulating film 213 is completed.

As is apparent from the above description, with the method for forming a trench device isolation film in a semiconductor device according to the present invention, the effective aspect ration of the trench can be lowered due to the oxygen implantation region with which the trench is filled. In addition, since the oxygen implantation region can be stabilized as the oxide film, voids can be prevented from being generated in the trench when the fill insulating film is formed.

Although the preferred embodiment of the present invention has been described in detail hereinabove, it should be clearly understood that many variations and/or modifications of the basic inventive concepts herein taught which may appear to those skilled in the present art will still fall within the spirit and scope of the present invention, as defined in the appended claims.

1. A method for forming a trench isolation film in a semiconductor device, comprising the steps of:
forming a trench in a device isolation field of a semiconductor substrate using a mask pattern on the semiconductor substrate;
implanting oxygen in a lower portion of the trench;
filling the trench, in which the oxygen is implanted, with a fill insulating film; and
annealing to compact the fill insulating film and stabilize the implanted oxygen as an oxide film.

2. The method of claim 1, wherein the mask pattern includes a first oxide film, a nitride film and a second oxide film sequentially formed on the semiconductor substrate, configured to expose the device isolation field of the semiconductor substrate.

3. The method of claim 2, wherein the first oxide film comprises a pad oxide film, and the second oxide film comprises a TEOS film.

4. The method of claim 1, wherein the fill insulating film comprises a high density plasma oxide film.
